(19) United States
(12) Patent Application Publication
(10) Pub. No.: US 2014/0124810 A1
(43) Pub. Date: May 8, 2014

(54) LIGHT EMITTING DEVICE AND LIGHT EMITTING DEVICE PACKAGE HAVING THE SAME

(71) Applicants: Sang Il Kim, Seoul (KR); Dong Hun Kang, Seoul (KR); Jong Ho Na, Seoul (KR); Yong Seon Song, Seoul (KR)

(72) Inventors: Sang Il Kim, Seoul (KR); Dong Hun Kang, Seoul (KR); Jong Ho Na, Seoul (KR); Yong Seon Song, Seoul (KR)

(21) Appl. No.: 14/068,429

(22) Filed: Oct. 31, 2013

(30) Foreign Application Priority Data
Nov. 7, 2012 (KR) 10-2012-0125165

(51) Int. Cl. H01L 33/58

(52) U.S. Cl. CPC H01L 33/58
USPC 257/98

(57) ABSTRACT

A light emitting device includes a substrate and a plurality of protrusions protruding from a top surface of the substrate. A first semiconductor layer is provided on top surfaces of the protrusions and a plurality of seed patterns protrudes from a bottom surface of the first semiconductor layer toward the protrusions. A medium layer is provided between the protrusions and a light emitting structure on a top surface of the first semiconductor layer. The bottom surface of the first semiconductor layer is located at a higher position than that of each of the protrusions, and the first semiconductor layer contacts a c-plane of each protrusion.

### CROSS-REFERENCE TO RELATED APPLICATIONS

The present application claims priority under 35 U.S.C. §119(a) of Korean Patent Application No. 10-2012-0125165 filed on Nov. 7, 2012, which is hereby incorporated by reference in its entirety.

### BACKGROUND

1. Field

The embodiment relates to a light emitting device.

The embodiment relates to a light emitting device package.

2. Background

Studies for a light emitting device package having a light emitting device have been actively pursued.

A light emitting device, which is made of, for example, a semiconductor material, is a semiconductor light emitting device or a semiconductor light emitting diode to convert electrical energy into light energy.

When comparing with conventional light sources such as a fluorescent lamp, and an incandescent lamp, the semiconductor light emitting device has advantages such as low power consumption, a semi-permanent life span, a rapid response speed, safety, and an eco-friendly property. In this regard, various studies have been performed to replace the conventional light sources with the LEDs.

The light emitting devices or light emitting device packages are increasingly used as light sources for lighting devices, such as various lamps used in indoors and outdoors, liquid crystal displays, electric signboards, and street lamps.

The above references are incorporated by reference herein where appropriate for appropriate teachings of additional or alternative details, features and/or technical background.

### BRIEF DESCRIPTION OF THE DRAWINGS

The embodiments will be described in detail with reference to the following drawings in which like reference numerals refer to like elements wherein:

FIG. 1 is a sectional view showing a light emitting device according to an embodiment.

FIG. 2 is a perspective view showing the light emitting device of FIG. 1.

FIG. 3 is a perspective view showing the substrate of FIG. 1.

FIG. 4 is a plane view showing the substrate of FIG. 1.

FIGS. 5 to 9 are views illustrating a process of fabricating a light emitting device according to an embodiment.

FIG. 10 is a sectional view showing a lateral-type light emitting device according to an embodiment.

FIG. 11 is a sectional view showing a flip-type light emitting device according to an embodiment.

FIG. 12 is a sectional view showing a vertical-type light emitting device according to an embodiment.

FIG. 13 is a sectional view showing a light emitting device package according to an embodiment.

### DETAILED DESCRIPTION

In the following description of the embodiments, it will be understood that, when an element is referred to as being formed “on” or “under” another element, two elements may make direct contact with each other, or one or more element may be interposed between two elements. Further, it will be understood that, when an element is referred to as being “on” or “under” another element, the element may be formed in an upper or down direction based on one element.

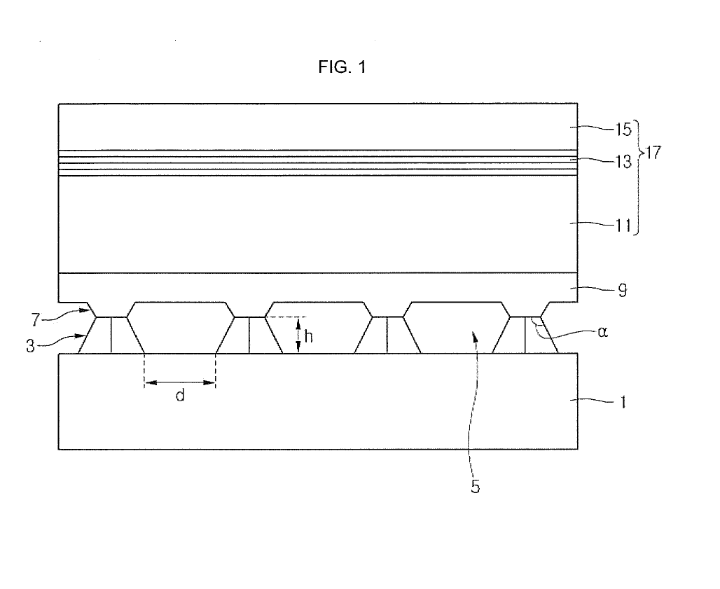

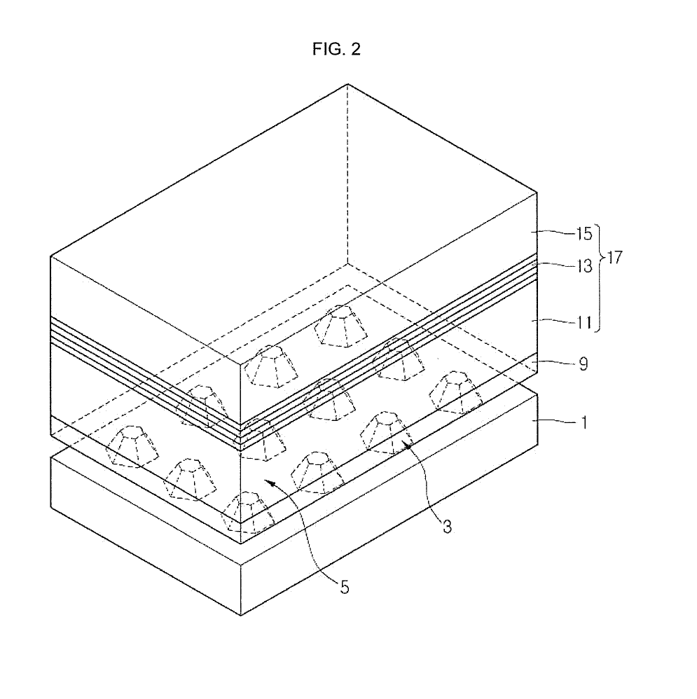

FIG. 1 is a sectional view showing a light emitting device according to an embodiment. FIG. 2 is a perspective view showing the light emitting device of FIG. 1.

Referring to FIG. 1, the light emitting device according to the embodiment may include a substrate 1, a buffer layer 9 and a light emitting structure 17, but the embodiment is not limited thereto.

The light emitting structure 17 may include a first conductive semiconductor layer 11, an active layer 13, and a second conductive semiconductor layer 15, but the embodiment is not limited thereto.

The light emitting device according to the embodiment may further include another semiconductor layer (not shown) disposed under and/or on the light emitting structure 17.

The light emitting device according to the embodiment may further include an undoped semiconductor layer (not shown) interposed between the buffer layer 9 and the light emitting structure 17.

The substrate 1 performs a function of easily growing the light emitting structure 17, but the embodiment is not limited thereto.

In order to stably grow the light emitting structure 17, the substrate 1 may include a material making a smaller lattice constant difference from that of the light emitting structure 10.

The light emitting device according to the embodiment may include a plurality of protrusions 3 protruding from a top surface of the substrate 1.

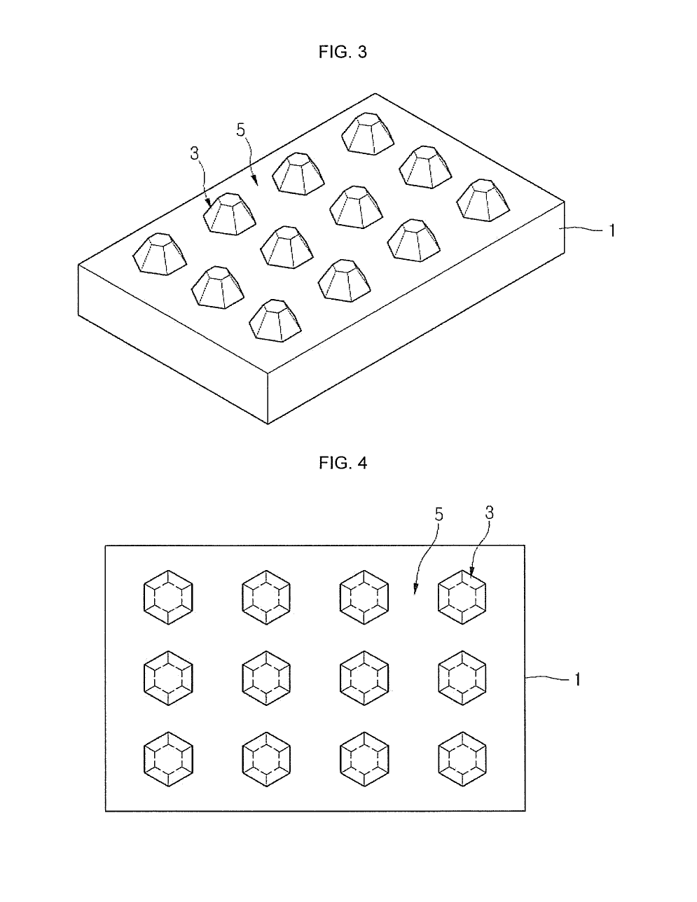

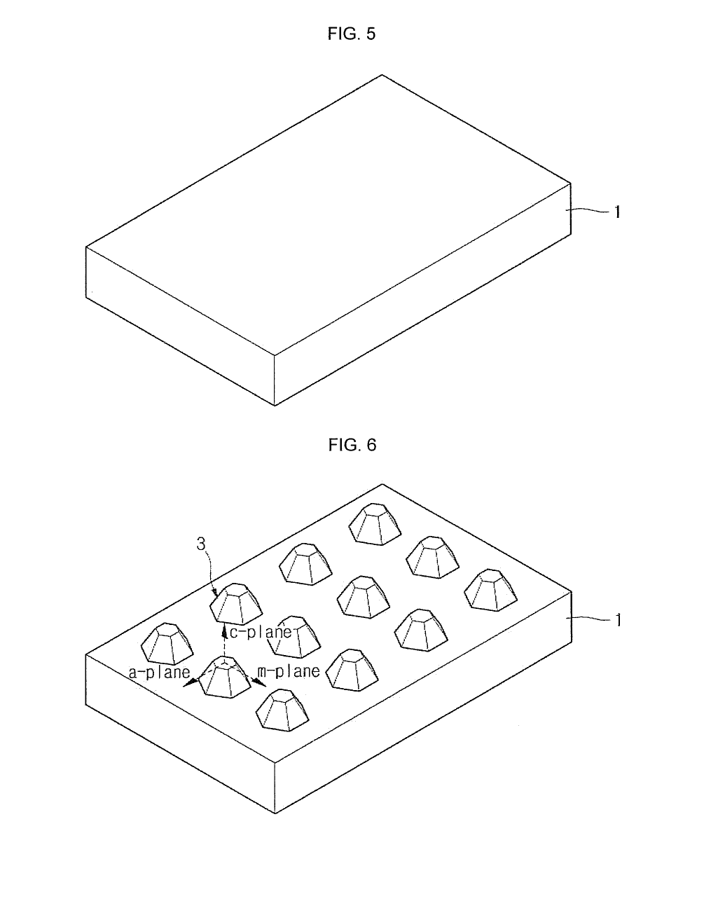

As shown in FIGS. 3 and 4, each protrusion 3 may have a hexahedral shape, but the embodiment is not limited thereto. That is, each protrusion 3 may have one top surface and six side surfaces, but the embodiment is not limited thereto.

The gap between the protrusions 3 may be constant or random, but the embodiment is not limited thereto.

The protrusions 3 may have a regular shape or a random shape, but the embodiment is not limited thereto.

A side of the protrusion 3 may have an inclined surface to the top surface of the substrate 1, but the embodiment is not limited thereto.

For example, the side surface of the protrusion 3 may have an angle α in the range of 90° to 150° with respect to the top surface of the protrusion 3, but the embodiment is not limited thereto.

For example, the protrusion 3 may have a height h in the range of 2 μm to 4 μm, but the embodiment is not limited thereto. For example, the top surface of the protrusion 3 may include a flat surface, but the embodiment is not limited thereto. For example, a gap d between the protrusions 3 may be in the range of 1 μm to 20 μm when measured at bottoms of the protrusions 3, but the embodiment is not limited thereto.

A size of the upper portion of the protrusion 3 may be smaller than that of the lower portion of the protrusion 3, but the embodiment is not limited thereto.

The buffer layer 9 may be formed on the top surface of the protrusion 3. A seed pattern 7, which makes contact with the top surface of the protrusion 3, may be formed on the bottom surface of the buffer layer 9.

As the buffer layer 9 is more grown, the seed patterns 7 may be merged with each other.

The seed pattern 7 may be easily grown along c-plane of the protrusion 3 and the seed pattern 7 is rarely grown in the direction having an angle of ±15° with respect to a-plane of the protrusion 3. The seed pattern 7 is more easily grown in an a-plane direction than the direction having an angle of ±15° with respect to a-plane. That is, the seed pattern 7 is rarely grown in the direction having an angle of ±15° with respect to a-plane of the protrusion 3, the seed pattern 7 is more easily grown in the a-plane direction than the direction having an angle of ±15° with respect to the a-plane of the protrusion 3, and the seed pattern 7 may be grown best along c-plane of the protrusion 3.

Thus, although not shown, a side surface of the seed pattern 7 may have a concave-convex shape partly protruding in a side direction along the circumference of the seed pattern 7, but the embodiment is not limited thereto. In this case, a concave portion may be formed at ±15° about the a-plane of the protrusion 3 and a convex portion may be aligned in the a-plane direction of the protrusion 3, but the embodiment is not limited thereto.

The side shape and height of the seed pattern 7 may be changed according to the growing temperature and pressure, but the embodiment is not limited thereto.

The side surface of the seed pattern 7 may be symmetrical or asymmetrical to the side surface of the protrusion 3, but the embodiment is not limited thereto.

Since the buffer layer 9 is formed through the seed pattern 7, the possibility of causing a dislocation may be minimized, so that the layer quality of the buffer layer 9 may be improved and the layer quality of the light emitting structure 17 formed on the buffer layer 9 may be excellent.

Even though a dislocation is formed on the seed pattern 7, the seed pattern 7 is formed in a horizontal direction rather than a vertical direction due to the growing direction, so that the dislocation is formed on the buffer layer 9 in the horizontal direction. Thus, the dislocation formed on the buffer layer 9 in the horizontal direction does not exert influence on the light emitting structure 17 formed on the buffer layer 9, so that any dislocations may be not caused in the light emitting structure 17, so the layer quality may be excellent and the optical and electrical characteristics may be improved.

Since the seed pattern 7 and the buffer layer 9 are formed on the protrusion 3, a medium layer 5 may be formed by the substrate 1, the protrusion 3, the seed pattern 7 and the buffer layer 9. The medium layer 5 may include air, but the embodiment is not limited thereto. That is, after a passage passing through an outside of the medium layer 5 of the light emitting device is closed, a liquid such as oil may be formed in the medium layer 5.

The buffer layer 9 may be formed to alleviate a lattice constant difference between the substrate 1 and the light emitting structure 17. The buffer layer 9 may be a buffer layer.

The buffer layer 9 may be formed of a group II-VI compound semiconductor material or a group III-V compound semiconductor material. For example, the buffer layer 9 may be formed in a multiple-layer structure including at least one of GaN, InN, AlGaN and InGaN, but the embodiment is not limited thereto.

The light emitting structure 17 may be formed on the buffer layer 9. For example, the light emitting structure 17 may include the first conductive semiconductor layer 11, the active layer 13 and the second conductive semiconductor layer 15. The first conductive semiconductor layer 11 may be formed on the buffer layer 9, the active layer 13 may be formed on the first conductive semiconductor layer 11, and the second conductive semiconductor layer 15 may be formed on the active layer 13.

For example, the first conductive semiconductor layer 11 may be an N-type semiconductor including an N-type dopant. For example, the first conductive semiconductor layer 11 may be formed of the semiconductor material having the compositional formula of InxAlyGa1-x-yN (0≦x≦1, 0≦y≦1, 0≦x+y≦1). For example, the first conductive semiconductor layer 11 may include at least one selected from the group consisting of InAlGaN, GaN, AlGaN, InGaN, AlN, InN and AlInN, and may be doped with an N-type dopant such as Si, Ge or Sn.

The active layer 13 may be formed on the first conductive semiconductor layer 11.

The active layer 13 emits light having a wavelength corresponding to an energy band gap between the materials constituting the active layer 13 by combining the first carrier, for example, electrons injected through the first conductive semiconductor layer 11 with the second carrier, for example, holes.

The active layer 13 may include one of an SQW (single quantum well) structure, an MQW (multiple quantum well) structure, a quantum wire structure or a quantum dot structure. The active layer 13 may have the stack structure in which a cycle of well and barrier layers including group II-VI or III-V compound semiconductors are repeatedly formed. For example, the active layer 7 may be formed in the stack structure of InGaN/GaN, InGaN/AlGaN, InGaN/InGaN. The energy bandgap of the barrier layer may be greater than energy the bandgap of the well layer.

The second conductive semiconductor layer 15 may be formed on the active layer 13. For example, the second conductive semiconductor layer 15 may include a P-type semiconductor layer including P-type dopants. The second conductive semiconductor layer 15 may be formed of a semiconductor material having the compositional formula of InxAlyGa1-x-yN (0≦x≦1, 0≦y≦1, and 0≦x+y≦1). For example, the second conductive semiconductor layer 15 may include at least one selected from the group consisting of InAlGaN, GaN, AlGaN, InGaN, AlN, InN and AlInN, and may be doped with P-type dopants such as Mg, Zn, Ca, Sir, or Ba.

Although it is described in the embodiment that the buffer layer 9 is formed on the protrusion 3, the first conductive semiconductor layer 11 of the light emitting structure 17 may be directly formed on the protrusion 3 of the first conductive semiconductor layer 11 instead of the buffer layer 9, but the embodiment is not limited thereto.

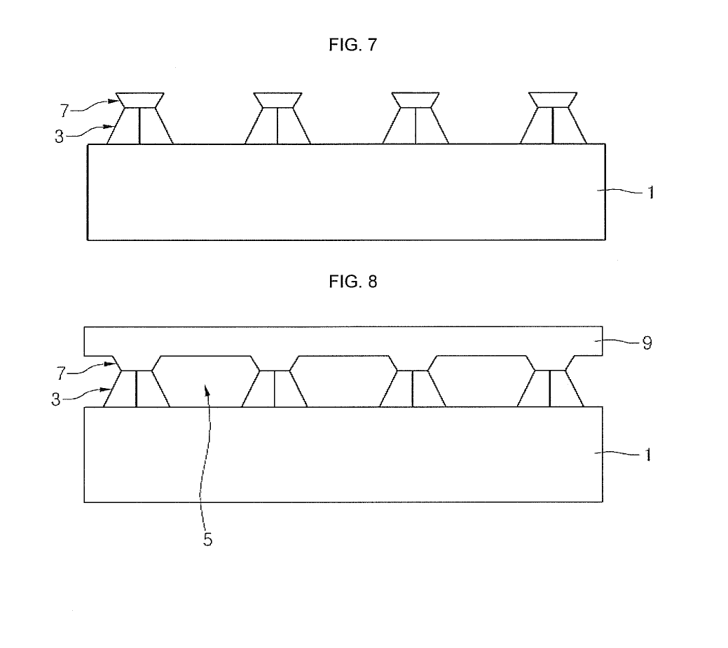

FIGS. 5 to 9 are views illustrating a process of fabricating a light emitting device according to an embodiment.

Referring to FIG. 5, the substrate 1 may be prepared. In order to stably grow the light emitting structure 17, the substrate 1 may include a material making a smaller lattice constant difference from that of the light emitting structure 17.

The substrate 1 may include at least one selected from the group consisting of Al2O3, SiC, Si, GaAs, GaN, ZnO, Si, GaP, InP and Ge.

Referring to FIG. 6, the plurality of protrusions 3 may be formed by etching the top surface of the substrate 1.

The protrusion 3 may be formed in a hexahedral shape, but the embodiment is not limited thereto.

The direction between the side surfaces of the protrusion 3 may be an a-plane, the direction of the side surface of the protrusion 3 may be an m-plane, and the direction of the top surface of the protrusion 3 may be a c-plane.

Referring to FIG. 7, the seed pattern 7 may be formed on the top surface of the protrusion 3. The seed pattern 7 may have a function of forming the buffer layer 9 in a subsequent process and may be formed of the same material as that of the buffer layer 9.

The seed pattern 7 and the buffer layer 9 may be formed of a group II-VI compound semiconductor material or a group III-V compound semiconductor material.

Atoms of the compound semiconductor material of the seed pattern 7 may be arrayed at 30° about atoms of the protrusion 3, but the embodiment is not limited thereto.

The seed pattern 7 is grown at the fastest speed in the c-plane direction corresponding to the top surface of the protrusion 3, is grown at the slower speed in the direction of ±15° about the a-plane than that of the c-plane direction, and is not grown in the a-plane direction.

Thus, the side surface of the seed pattern 7 may have an inclined surface to the top surface of the protrusion 3, and may be symmetrical or asymmetrical with the side surface of the protrusion 3 about the top surface of the protrusion 3, but the embodiment is not limited thereto.

The side surface of the seed pattern 7 may have a concave-convex shape partly protruding along a periphery of the side surface in a side direction, but the embodiment is not limited thereto.

Referring to FIG. 8, the buffer layer 9 is continuously grown on the seed pattern 7 with the same material as that of the seed pattern 7, so that the buffer layer 9 may be combined between the seed patterns 7.

Referring to FIG. 9, the light emitting structure 17 including the first conductive semiconductor layer 11, the active layer 13 and the second conductive semiconductor layer 15 may be formed on the buffer layer 9.

The buffer layer 9 and the light emitting structure 17 may be formed of a group II-VI or III-V compound semiconductor material, but the embodiment is not limited thereto.

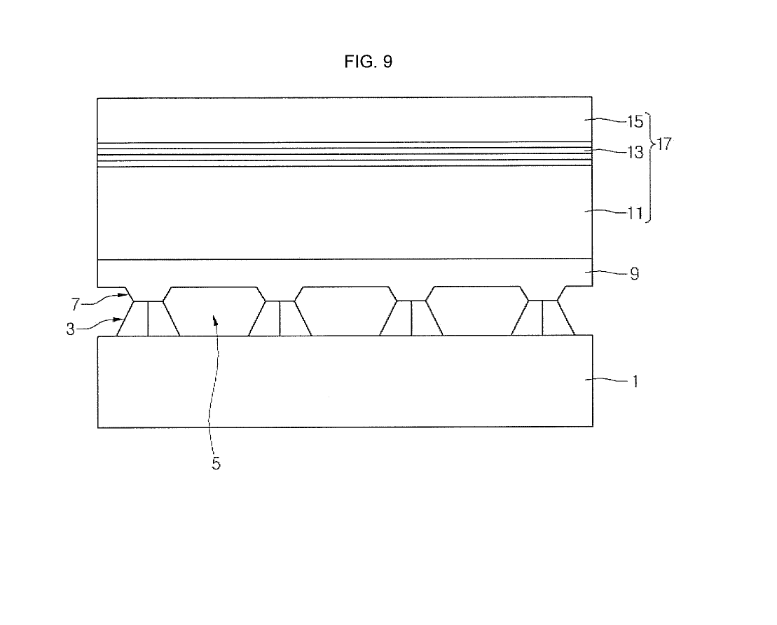

FIG. 10 is a sectional view showing a lateral-type light emitting device according to the embodiment.

Referring to FIG. 10, the lateral-type light emitting device may include a substrate 1, a medium layer 5, a first conductive semiconductor layer 11, an active layer 13, a second conductive semiconductor layer 15, a transparent conductive layer 21 and first and second electrodes 23 and 25.

In the embodiment of FIG. 10, the same reference numerals will be assigned to elements having the same functions as those of FIG. 1, and details thereof will be omitted in order to avoid redundancy.

A plurality of protrusions 3 may be formed on the substrate 1 and the medium layer 5 may be formed by the protrusions 3, for example, in spaces between the protrusions 3, but the embodiment is not limited thereto.

The medium layer 5 may be a liquid such as oil or air, the embodiment is not limited thereto.

The medium layer 5 may be surrounded by the substrate 1, the protrusion 3, the seed pattern 7 and the buffer layer 9.

The seed pattern 7 may be formed on the bottom surface of the buffer layer 9 and may make contact with the top surface of the protrusion 3.

The first conductive semiconductor layer 11, the active layer 13 and the second conductive semiconductor layer 15 may constitute the light emitting structure 17.

A transparent conductive layer 21 may be formed on the second conductive semiconductor layer 15 and a second electrode 25 may be formed in a region on the transparent conductive layer 21.

A first electrode 23 may be formed in a region on the first conductive semiconductor layer 11. To this end, through a mesa etching, the second conductive semiconductor layer 15, the active layer 13 and a portion of the top surface of the first conductive semiconductor layer 11 may be removed. Then, the first electrode 23 may be formed the first conductive semiconductor layer 11.

Since the second electrode 25 is formed on the uppermost portion of the lateral-type light emitting device and the first electrode 23 is formed on a side surface of the lateral-type light emitting device according to the embodiment, when an electric power is applied to the first and second electrodes 23 and 25, current flows into the light emitting structure 17 which is the shortest path between the first and second electrodes 23 and 25, so that any light may be not emitted from the entire region of the active layer 13.

Therefore, since the transparent conductive layer 21 is formed on the entire region of the second conductive semiconductor layer 15 between the second conductive semiconductor layer 15 and the second electrode 25, the current spreads over the entire region of the transparent conductive layer 21 through the second electrode 25 so that the current flows between the first electrode 23 and the entire region of the transparent conductive layer 21. Thus, the light is emitted from the entire region of the active layer 13 so that the light emitting efficiency may be improved.

The transparent conductive layer 21 may be formed of a conductive material having excellent transparence and conductivity. For example, the transparent conductive layer 21 may include at least one selected from the group consisting of ITO, IZO(In—ZnO), GZO(Ga—ZnO), AZO(Al—ZnO), AGZO(Al—Ga ZnO), IGZO(In—Ga ZnO), IrOx, RuOx, RuOx/ITO, Ni/IrOx/Au and Ni/IrOx/Au/ITO.

For example, the first and second electrodes 23 and 25 may include one selected from the group consisting of Al, Ti, Cr, Ni, Pt, Au, W, Cu and Mo, or an alloy thereof, but the embodiment is not limited thereto.

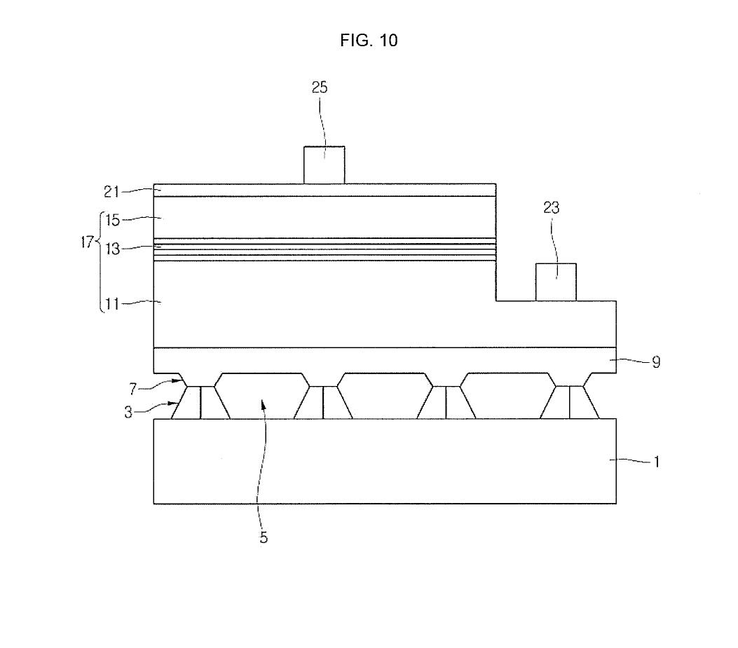

FIG. 11 is a sectional view showing a flip-type light emitting device according to the embodiment.

The embodiment of FIG. 11 is almost similar with that of FIG. 10, except for a reflective layer 27 substituting for the transparent conductive layer 21 of FIG. 10. Thus, in the embodiment of FIG. 11, the same reference numerals will be assigned to elements having the same shapes and functions as those of FIG. 10, and details thereof will be omitted in order to avoid redundancy.

Referring to FIG. 11, the flip-type light emitting device may include a substrate 1, a medium layer 5, a first conductive semiconductor layer 11, an active layer 13, a second conductive semiconductor layer 15, a reflective layer 27 and first and second electrodes 31and 33.

The first conductive semiconductor layer 11, the active layer 13 and the second conductive semiconductor layer 15 may constitute the light emitting structure 17.

The reflective layer 27 may be formed below the second conductive semiconductor layer 15 and the second electrode 33 may be formed below the reflective layer 27.

The reflective layer 27 may be formed below the active layer 13 such that the light propagated in a lower direction may be reflected. The reflective layer 27 may include at least one selected from the group consisting of Ag, Ni, Al, Rh, Pd, Ir, Ru, Mg, Zn, Pt, Au and Hf, or a lamination thereof, but the embodiment is not limited thereto.

The first electrode 31 may be formed below the first conductive semiconductor layer 11.

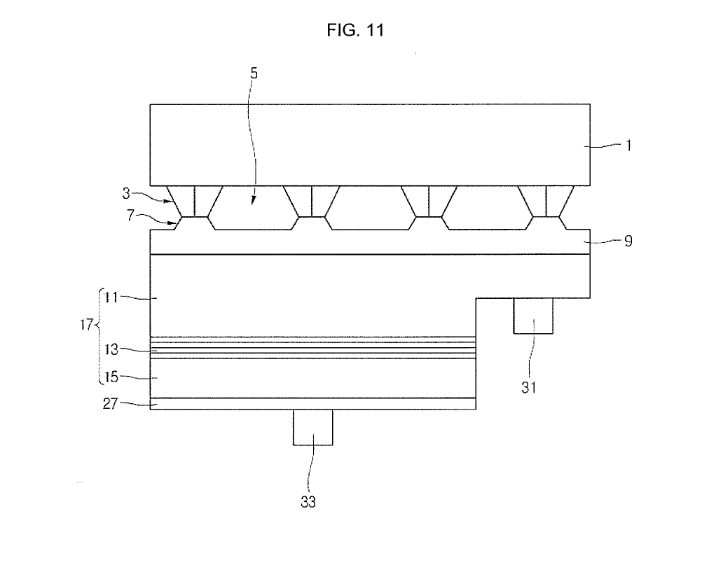

FIG. 12 is a sectional view showing a vertical-type light emitting device according to the embodiment.

Instead of the first and second electrodes 23 and 25 of FIG. 10 or the first and second electrodes 31 and 33 of FIG. 11, an electrode 55 and an electrode layer 45 are provided in the embodiment of FIG. 12, where the electrode 55 and the electrode layer 45 may be vertically overlapped with each other. In addition, in the embodiment of FIG. 12, since the electrode layer 45 at least has a size and reflexibility greater than those of the active layer 13 of the light emitting structure 17, the electrode layer 45 may reflect forward the light generated from the active layer 13, so that the light emitting efficiency may be improved.

An electrode 55 of the embodiment of FIG. 12 may have the same structure, shape, material and function as those of the first and second electrodes 23 and 25 of FIG. 10 or the first and second electrodes 31 and 33 of FIG. 11. Thus the detailed description of the electrode 55 of FIG. 12 will be omitted and the omitted description will be easily understood by referring to the above description.

Referring to FIG. 12, the vertical-type light emitting device according to the embodiment may include a supporting substrate 41, a bonding layer 43, an electrode layer 45, a current blocking layer (CBL) 49, a first conductive semiconductor layer 11, an active layer 13, a second conductive semiconductor layer 15, a light extraction structure 53, a protective layer 51 and an electrode 55.

The first conductive semiconductor layer 11, the active layer 13 and the second conductive semiconductor layer 15 may constitute the light emitting structure 17.

The supporting substrate 41, the bonding layer 43 and the electrode layer 45 may constitute an electrode member for supplying electric power.

The supporting substrate 41 may support a plurality of layers thereon and may perform an electrode function. The supporting substrate 41 may supply an electric power to the electrode 55 and the light emitting structure 17.

The supporting substrate 41 may be formed of a metallic material or a semiconductor material, but the embodiment is not limited thereto. The supporting substrate 41 may be formed of a material having high electrical conductivity and thermal conductivity. For example, the supporting substrate 41 may be a metallic material including at least one selected from the group consisting of Ti, Cr, Ni, Al, Pt, Au, W, Cu, Cu alloy, Mo and Cu—W. For example, the supporting substrate 41 may be a semiconductor material including at least one selected from the group consisting of Si, Ge, GaAs, GaN, ZnO, SiGe and SiC.

The bonding layer 43 may be formed on the supporting substrate 41. The bonding layer 43 is formed between the electrode layer 45 and the supporting substrate 41. The bonding layer 43 may serve as a medium for enhancing the adhesion between the electrode layer 45 and the supporting substrate 41.

The bonding layer 43 may be formed of a metallic material having high bonding characteristic and thermal conductivity. For example, the bonding layer 43 may include at least one selected from the group consisting of Ti, Au, Sn, Ni, Nb, Cr, Ga, In, Bi, Cu, Ag and Ta.

The top surface of the bonding layer 43 may have a groove which is formed to allow the periphery region to extend in the upper direction, that is, toward the light emitting structure 17, the embodiment is not limited thereto. The electrode layer 43 may make contact with the central region of the top surface of the bonding layer 43 or may be formed on the groove, but the embodiment is not limited thereto.

Some region of the electrode layer 45 may vertically overlap with a bottom surface of the channel layer 47. In other words, the inner region of the channel layer 47 may pass through an end of the electrode layer 45 and extend to an inside of the channel layer 47.

The electrode layer 45 may reflect the light incident from the light emitting structure 17, so that the light extraction efficiency may be improved.

The electrode layer 45 may make ohmic contact with the light emitting structure 17, so that the current may flow into the light emitting structure 17.

The electrode layer 45 may be formed in single layer having a mixture of a reflective material and an ohmic material. In this case, there is no need to separately form the reflective layer and the ohmic contact layer to form the electrode layer 45. For example, the reflective material may include at least one selected from Ag, Ni, Al, Rh, Pd, Ir, Ru, Mg, Zn, Pt, Au and Hf, or an alloy thereof, but the embodiment is not limited thereto. The ohmic contact material may include a transparent conductive material. For example, the ohmic contact material may include at least one selected from the group consisting of ITO (indium tin oxide), IZO (indium zinc oxide), IZTO (indium zinc tin oxide), IAZO (indium aluminum zinc oxide), IGZO (indium gallium zinc oxide), IGTO (indium gallium tin oxide), AZO (aluminum zinc oxide), ATO(antimony tin oxide), GZO (gallium zinc oxide), IrOx, RuOx, RuOx/ITO, Ni, Ag, Ni/IrOx/Au, and Ni/IrOx/Au/ITO.

The electrode layer 45 may be formed in a multi-layer structure including one of IZO/Ni, AZO/Ag, IZO/Ag/Ni and AZO/Ag/Ni.

The current blocking layer 49 may be formed on the electrode layer 45. The current blocking layer may be formed to make contact with the bottom surface of the light emitting structure 17. At least a portion of the current blocking layer 49 may vertically overlap with the electrode 55.

The current blocking layer 49 may be formed on the top surface of the electrode layer 45, but the embodiment is not limited thereto. That is, although not shown, the current blocking layer 49 may be formed on the bottom surface of the light emitting structure 17, the bottom surface of the electrode layer 45 or the top surface of the bonding layer 43.

The current blocking layer 49 may make Schottky contact with the light emitting structure 17. Thus, the current does not smoothly supplied into the light emitting structure 17 making schottky contact with the current blocking layer 49.

The channel layer 47 may be formed on the electrode layer 45. For example, the channel layer 47 may be formed around the edge region of the electrode layer 45. That is, the channel layer 47 may be formed on circumference region between the light emitting structure 17 and the electrode layer 45.

The channel layer 47 prevents a short circuit from being formed between the side surface of the bonding layer 43 and the side surface of the light emitting structure 17 due to an external foreign substance. In addition, by securing an area on which the channel layer 47 makes contact with the light emitting structure 17, when a laser scribing process for dividing the plurality of chips into individual chip units and a laser lift off process for removing a substrate (reference numeral 1 of FIG. 1) are performed, the light emitting structure 17 may be effectively prevented from being delaminated from the electrode layer 45.

The channel layer 47 may include an insulation material. For example, the channel layer 47 may include at least one selected from the group consisting of SiO2, SiOx, SiOxNy, Si3N4, and Al2O3. Further, the channel layer 47 may be formed of a metallic material, but the embodiment is not limited thereto.

The light emitting structure 17 may be formed on the electrode layer 45, the channel layer 47 and the current blocking layer 49.

The side surface of the light emitting structure 17 may be perpendicularly formed or inclined through an etching process which is performed for dividing the plurality of chips into individual chip units. For example, the side surface of the light emitting structure 17 may be formed through an isolation etching.

The light extraction structure 53 for extracting light may be formed on the top surface of the first conductive semiconductor layer 11.

The light extraction structure 53 may be formed by the seed pattern 7 depicted in FIG. 1. The seed pattern 7 may have a function of forming the buffer layer 9. The seed pattern 7 may be formed from the top surfaces of the plurality of protrusions 3 and then the portions between the seed patterns 7 may be merged after a predetermined time has elapsed, so that the buffer layer 9 may be formed. Thus, the concavo-convex pattern may be formed by the seed pattern 7 until the buffer layer 9 is formed from the top surfaces of the protrusions 3, so that the light extraction may be increased by the concavo-convex pattern.

Thus, since there is no need to additionally form the light extraction structure 53 in the vertical-type light emitting device, the process may be simplified and the process time may be reduced.

The light extraction structure 53 may have a roughness structure, but the embodiment is not limited thereto.

The electrode 55 may be formed on the first conductive semiconductor layer 11.

The electrode 55 may have a pattern shape partly formed without covering the entire area of the light emitting structure 17.

The protective layer 51 may be formed on the light emitting structure 17. For example, the protective layer 51 may be formed at least on the side surface of the light emitting structure 17.

The protective layer 51 may prevent the light emitting structure 17 from being short-circuited to the supporting substrate 41 and in addition, may protect the vertical-type light emitting device against an impact from an outside. For example, the protective layer 51 may include one selected from the group consisting of SiO2, SiOx, SiOxNy, Si3N4, TiO2 and Al2O3, but the embodiment is not limited thereto.

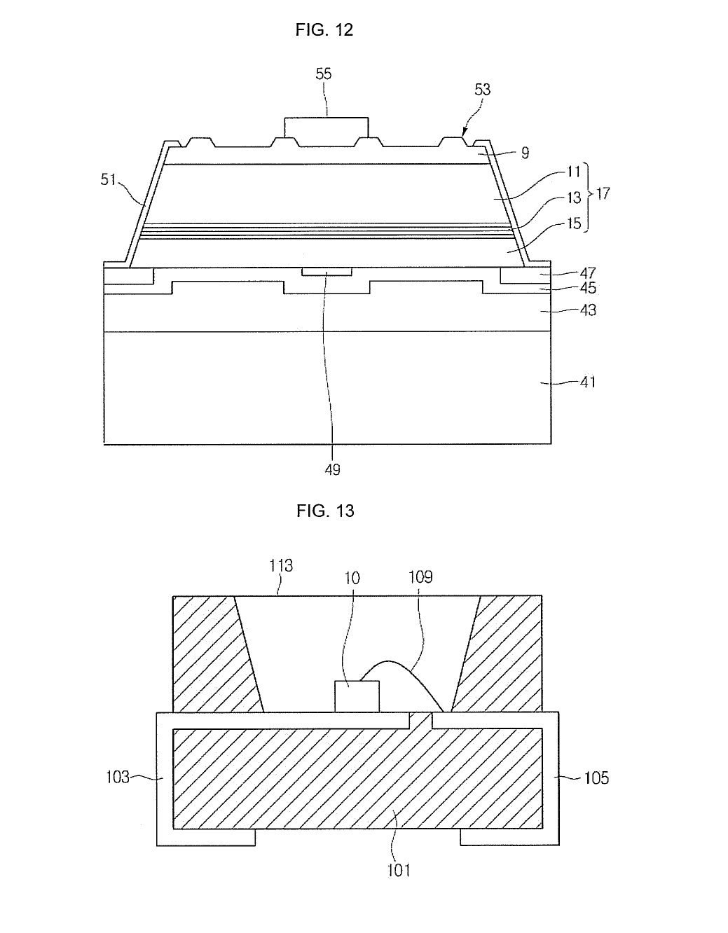

FIG. 13 is a sectional view showing a light emitting device package according to an embodiment.

Referring to FIG. 13, the light emitting device package according to the embodiment includes a body 101, first and second lead electrodes 103 and 105 installed in the body 101, a light emitting device 10 installed on the body 101 to receive an electric power from the first and second lead electrodes 103 and 105 according to the first and second embodiments, and a molding member 113 surrounding the light emitting device 10.

The body 101 may include a silicon material, a polysilicon resin material or a metallic material, and an inclined surface may be formed around the light emitting device 10.

The first and second lead electrodes 103 and 105 are electrically separated from each other, and the electric power is supplied to the light emitting device 10 through the first and second lead electrodes 103 and 105.

Further, the first and second lead electrodes 103 and 105 may reflect the light generated from the light emitting device 10 so that the light efficiency may be increased, and may dissipates the heat generated from the light emitting device 10.

The light emitting device may be mounted on one of the first and second lead electrodes 103 and 105 and the body 101 and may be electrically connected to the first and second lead electrodes 103 and 105 through a wire bonding scheme or a die bonding scheme, but the embodiment is not limited thereto.

Although it is exemplarily proposed in the embodiment that the light emitting device 10 is electrically connected to one of the first and second lead electrodes 103 and 105 through one wire 109, the embodiment is not limited thereto and the light emitting device 10 may be electrically connected to the first and second lead electrodes 103 and 105 through two wires. In addition, the light emitting device 10 may be electrically connected to the first and second lead electrodes 103 and 105 without using any wires.

The molding member 113 surrounds the light emitting device 10, so that the molding member 113 may protect the light emitting device 10. In addition, the molding member 113 may include a fluorescent material so that the wavelength of light emitted from the light emitting device may be changed.

The light emitting package 200 according to the embodiment may include a COB (Chip on Board) type of a light emitting package. The top surface of the light emitting package may be flat and a plurality of light emitting devices may the body 101 may be installed on the body 101.

The light emitting device or the light emitting package according to an embodiment may be applied to a light unit. The light unit may be applied to a display, a lighting apparatus and a unit such as a lamp, a traffic light, a vehicle headlight, an electric signboard or an indicator light.

According to an embodiment, due to the protrusions formed on the substrate, the light extraction efficiency may be improved.

According to an embodiment, due to the medium layer formed between the protrusions formed on substrate, the light extraction efficiency may be more improved.

According to an embodiment, by forming the buffer layer or the light emitting structure on only the protrusions, the crystalline property of the light emitting structure is improved so that the optical and electrical properties may be improved.

According to an embodiment, since the medium layer formed between the protrusions have a light reflecting function when the embodiment is applied to the lateral type light emitting device, the light extraction efficiency may be improved.

According to an embodiment, the medium layer formed between the protrusions constitutes the light extraction structure when the embodiment is applied to the flip-type light emitting device, so that the light extraction efficiency may be improved.

According to an embodiment, the seed pattern constitutes the light extraction structure when the embodiment is applied to the vertical type light emitting device, so that the light extraction efficiency may be improved.

An embodiment provides a light emitting device capable of improving a light extraction.

An embodiment provides a light emitting device which can be grown in a good quality.

An embodiment provides a light emitting device package including a light emitting device.

According to an embodiment, there is provided a light emitting device including a substrate; a plurality of protrusions disposed on the substrate and spaced apart from each other; a first semiconductor layer on top surfaces of the protrusions; a medium layer between the protrusions; and a light emitting structure on the first semiconductor layer, wherein the first semiconductor layer is formed along a c-plane of the protrusions, and a bottom surface of the first semiconductor layer includes a seed pattern.

According to an embodiment, there is provided a light emitting device package includes a body; first and second lead electrodes on the body; a light emitting device on one of the first and second lead electrodes; and a molding member surrounding the light emitting device.

Any reference in this specification to “one embodiment,” “an embodiment,” “example embodiment,” etc., means that a particular feature, structure, or characteristic described in connection with the embodiment is included in at least one embodiment of the invention. The appearances of such phrases in various places in the specification are not necessarily all referring to the same embodiment. Further, when a particular feature, structure, or characteristic is described in connection with any embodiment, it is submitted that it is within the purview of one skilled in the art to effect such feature, structure, or characteristic in connection with other ones of the embodiments.

Although embodiments have been described with reference to a number of illustrative embodiments thereof, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. A light emitting device comprising:
a substrate;
a plurality of protrusions protruding from a top surface of the substrate;
a first semiconductor layer on top surfaces of the protrusions;
a plurality of seed patterns protruding from a bottom surface of the first semiconductor layer toward the protrusions;
a medium layer between the protrusions; and
a light emitting structure on a top surface of the first semiconductor layer,
wherein the bottom surface of the first semiconductor layer is located at a higher position than that of the protrusions, and
the first semiconductor layer contacts a c-plane of each of the plurality of protrusions.

2. The light emitting device of claim 1, wherein each of the plurality of seed patterns contacts top surfaces of the protrusions.

3. The light emitting device of claim 1, wherein side surfaces of the seed patterns are asymmetrical to side surfaces of the protrusions with respect to top surfaces of the protrusions, respectively.

4. The light emitting device of claim 1, wherein a bottom surface of each of the seed patterns has a width narrower than that of a top surface of each of the seed patterns.

5. The light emitting device of claim 1, wherein side surfaces of the seed patterns protrude in an a-plane direction of the protrusions rather than a direction having an angle of ±15° with respect to the a-plane of the protrusions.

6. The light emitting device of claim 1, wherein the medium layer contacts the substrate, the protrusions, the seed patterns and the first semiconductor layer.

7. The light emitting device of claim 1, wherein side surfaces of the protrusions are inclined at an angle in a range of 90° to 150° with respect to the top surfaces of the protrusions.

8. The light emitting device of claim 1, wherein an interval between the protrusions is in a range of 1 μm to 20 μm.

9. The light emitting device of claim 1, wherein a height of each protrusion is in a range of 2 μm to 4 μm.

10. The light emitting device of claim 1, wherein the medium layer includes a liquid or air.

11. The light emitting device of claim 1, wherein the first semiconductor layer includes a buffer layer or an n-type semiconductor layer.

12. The light emitting device of claim 1, wherein each of the protrusions includes six inclined side surfaces and top flat surfaces on the six inclined side surfaces.

13. The light emitting device of claim 1, wherein the substrate and the protrusions include a sapphire material.

14. A light emitting device comprising:
a substrate;
a plurality of protrusions protruding from a top surface of the substrate;
a first semiconductor layer on top surfaces of the protrusions;
a plurality of seed patterns protruding from a bottom surface of the first semiconductor layer toward the protrusions;
a medium layer between the protrusions; and
a light emitting structure on a top surface of the first semiconductor layer,
wherein the protrusions include a plurality of inclined side surfaces and a plurality of top flat surfaces,
a bottom surface of the first semiconductor layer is located at a higher position than that of each of the protrusions,
each of the seed patterns includes a bottom surface contacted with the top flat surface and a side surface inclined with respect to the bottom surface, and
each of the seed patterns contacts each of the protrusions.

15. The light emitting device of claim 14, wherein the substrate and the protrusions include a sapphire material, and
the first semiconductor layer includes one of GaN, InN, AlGaN and InGaN.

16. The light emitting device of claim 14, wherein the first semiconductor layer includes a buffer layer or an n-type semiconductor layer.

17. The light emitting device of claim 14, wherein a height of each protrusion is greater than a thickness of each seed patterns.

18. The light emitting device of claim 14, wherein a top surface of each of the protrusions has narrower width than that of a bottom surface of each of the protrusions, and
a top surface of each of the seed patterns has narrower width than that of a bottom surface of each of the seed patterns.

19. The light emitting device of claim 14, wherein entire bottom surfaces of the seed patterns overlap with top surfaces of the protrusions in a vertical direction.

20. The light emitting device of claim 14, wherein t each of the protrusion is formed in a hexahedral shape.
